(19) United States
(12) Patent Application Publication
(10) Pub. No.: US 2010/0033223 A1
(43) Pub. Date: Feb. 11, 2010

(54) FLIP-FLOP CIRCUIT

(75) Inventor: Keisuki Kiyomizu, Miyazaki (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI SEMICONDUCTOR CO., LTD., Tokyo (JP)

(21) Appl. No.: 12/507,824

(22) Filed: Jul. 23, 2009

(30) Foreign Application Priority Data
Aug. 11, 2008 (JP) 2008-206882

(51) Int. Cl. H03K 3/00

(52) U.S. Cl. 327/218

(57) ABSTRACT

A D-flip-flop includes a data input terminal for receiving a data signal, a clock input terminal for receiving a clock signal, a reset input terminal for receiving a reset signal, an output terminal for latching the data signal received through the data input terminal and outputting it as an output data signal in synchronism with the clock signal, and an inverted output terminal for outputting an inverted output data signal, obtained by inverting the output data signal output from the output terminal. The inverted output terminal is connected to the data input terminal. The clock signal output section includes an XNOR circuit and an OR circuit, and outputs the clock signal to the clock input terminal of the D-flip-flop in synchronism with the rise of the clock signal only when the data signal has changed.

### CROSS-REFERENCE TO RELATED APPLICATION

This application claims priority under 35 USC 119 from Japanese Patent Application No. 2008-206882 filed on Aug. 11, 2008, the disclosure of which is incorporated by reference herein.

### BACKGROUND OF THE INVENTION

1. Field of the Invention

This invention relates to a flip-flop circuit. Particularly, the invention relates to a low power consumption type flip-flop circuit that includes a D-flip-flop.

2. Description of the Related Art

A D-flip-flop is, usually, used as a circuit for holding the data. The D-flip-flop configured as shown in FIG. 11 is used when it is desired to delay an input signal by one clock. Further, the interior of the D-flip-flop 100 as shown in FIG. 11 is configured by a circuit as shown in, for example, FIG. 12.

In the circuit shown in FIG. 12, inverters 102 and 104 operate upon receipt of a clock signal, irrespectively to a change in the data signal that are inputted. Therefore, the circuit configured as shown in FIG. 12 may wastefully consume the power.

As shown in FIG. 13, JP-A No. 10-290143 discloses a low power consumption type memory circuit 106 with a flip-flop applied to a latch circuit. The memory circuit 106 with the low power consumption shown in FIG. 13 is provided with an exclusive OR circuit 110 and an AND circuit 112, in order to configure that a clock signal is input to a flip-flop circuit 108 only when a data signal changes.

Further, as shown in FIG. 11, JP-A No. 11-224136 discloses a flip-flop circuit configured to consume little power, like the circuit shown in FIG. 13, by using a D-flip-flop 100 shown in FIG. 11. This circuit is exemplified by a flip-flop circuit 120 of FIG. 14.

In the flip-flop circuit 120 as shown in FIG. 14, an XNOR circuit 122 and an OR circuit 124 permits a clock signal CLK to be input to the clock input terminal CK of the D-flip-flop, only when there is a change in the data signal input to an IN terminal. Due thereto, wasteful power consumption can be suppressed when there is no change in the data signal. However, if the output signal A of the XNOR circuit 122 is fixed to a low level due to some cause, the clock signal CLK is input to the clock input terminal CK of the D-flip-flop 100 at all times. Therefore, the D-flip-flop 126 normally operates as the D-flip-flop 100 shown in FIG. 11. In the flip-flop circuit 120 shown in FIG. 14, no change occurs in the output data signal OUT which is outputted from the output terminal Q of the D-flip-flop 126 before and after the fault, and therefore fault cannot be detected.

Further, when a scan test is executed by inserting a circuit for enabling the scan test in the flip-flop circuit 120, the fault cannot be detected, and the fault detection rate decreases.

### SUMMARY OF THE INVENTION

The present invention provides a flip-flop circuit that suppresses wasteful power consumption and prevents a decrease in the fault detection rate.

A first aspect of the invention is a flip-flop circuit including: a clock signal output section that receives a data signal and a clock signal, and outputs the clock signal in synchronism with the rise or the fall of the clock signal when the data signal changes; and a D-flip-flop including: a data input terminal that receives an input signal; a clock input terminal that receives the clock signal; an output terminal that latches and outputs the input signal in synchronism with the rise or the fall of the received clock signal; and an inverted output terminal that outputs an inverted output data signal obtained by inverting the output data signal output from the output terminal, wherein the inverted output terminal of the D-flip-flop is connected to the data input terminal.

According to the first aspect, when the data signal changes, the clock signal output section outputs the clock signal to the D-flip-flop that is synchronized with the rise or the fall of the clock signal. Therefore, according to the first aspect of the present invention, waste power consumption can be suppressed as compared to when the clock signals are inputted to the D-flip-flop at all times.

Further, according to the first aspect of the invention, the inverted output terminal of the D-flip-flop is connected to the data input terminal. Therefore, in case the clock signals are inputted to the clock input terminal of the D-flip-flop at all times, due to a fault in the clock signal output section, the output data signals outputted from the output terminal becomes high level and low level repetitively, and therefore makes it possible to detect a fault. Accordingly, the first aspect of the present invention can suppresses decrease in the fault detection rate.

In a second aspect of the invention, in the first aspect, the output terminal may latch and output the input signal in synchronism with the rise of the clock signal; and the clock signal output section may include, an XNOR circuit that outputs an XNOR signal which is a negation of an exclusive OR of the output data signal and the data signal; and an OR circuit that outputs an OR signal which is an OR of the XNOR signal and the clock signal.

In a third aspect of the invention, in the second aspect, may further include a selecting section that receives a scan enable signal that represents whether or not to permit an execution of a scan test, a scan data signal for scan test, and the inverted output data signal, that selects either the scan data signal or the inverted output data signal, depending on the scan enable signal, and that outputs the selected signal to the data input terminal, and an AND circuit that outputs an AND signal which is an AND of a signal obtained by inverting the scan enable signal and the XNOR signal.

When the outputs of the XNOR circuit are fixed to the low level due to the fault, the present invention configured as above can easily detect the fault by executing a scan test and by monitoring the output data signals.

In a fourth aspect of the invention, in the first aspect, the output terminal may latch and output the input signal in synchronism with the fall of the clock signal; and the clock signal output section may include, an XOR circuit that outputs an XOR signal which is an exclusive OR of the output data signal and the data signal, and an AND circuit that outputs an AND signal which is an AND of the XOR signal and the clock signal.

In a fifth aspect of the invention, in the fourth aspect, may further include a selection section that receives a scan enable signal that represents whether or not to permit an execution of a scan test, a scan data signal for scan test, and the inverted output data signal, that selects either the scan data signal or the inverted output data signal depending on the scan enable signal, and that outputs the selected signal to the data input terminal, and an OR circuit that outputs an OR signal which is an OR of the scan enable signal and the XOR signal.

In case when the outputs of the XNOR circuit are fixed to the high level, due to the fault, the present invention configured as above can easily detect the fault by executing the scan test and by monitoring the output data signals.

Accordingly, the present invention can suppress the wasteful power consumption and prevents a decrease in the fault detection rate.

### BRIEF DESCRIPTION OF THE DRAWINGS

Exemplary embodiments of the present invention will be described in detail based on the following figures, wherein:

FIG. 1 is a circuit diagram illustrating a flip-flop circuit according to a first exemplary embodiment;

FIG. 2 is a timing chart illustrating the operation of the flip-flop circuit according to the first exemplary embodiment;

FIG. 3 is a timing chart illustrating the operation of a flip-flop circuit according to related art;

FIG. 4 is a timing chart illustrating the operation of when a fault has occurred in the flip-flop circuit of the first exemplary embodiment;

FIG. 5 is a timing chart illustrating the operation of when a fault has occurred in the flip-flop circuit according to the related art;

FIG. 6 is a circuit diagram illustrating the flip-flop circuit according to a second exemplary embodiment;

FIG. 7 is a circuit diagram illustrating the flip-flop circuit according to a third exemplary embodiment;

FIG. 8 is a timing chart illustrating the operation of the flip-flop circuit according to the third exemplary embodiment;

FIG. 9 is a timing chart illustrating the operation of when a fault has occurred in the flip-flop circuit according to the third exemplary embodiment;

FIG. 10 is a circuit diagram illustrating the flip-flop circuit according to a fourth exemplary embodiment;

FIG. 11 is a diagram illustrating a D-flip-flop according to a related art;

FIG. 12 is a circuit diagram illustrating an internal circuit of the D-flip-flop according to the related art;

FIG. 13 is a circuit diagram illustrating a low power consumption type memory circuit according to the related art; and

FIG. 14 is a circuit diagram illustrating a low power consumption type flip-flop circuit according to the related art.

### DETAILED DESCRIPTION OF THE INVENTION

Exemplary embodiments of the present invention will be described below in detail with reference to the drawings.

### First Exemplary Embodiment

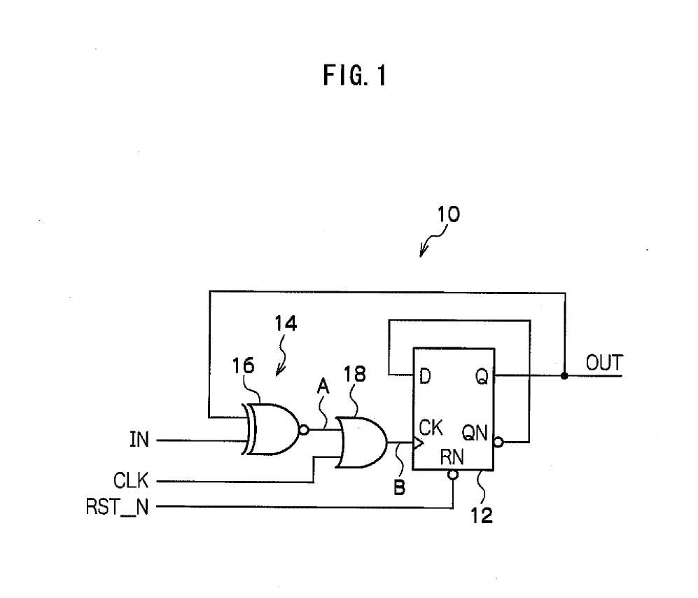

FIG. 1 shows a flip-flop circuit 10 according to a first exemplary embodiment of the present invention. The circuit constitution of the flip-flop circuit 10 will be described below.

The flip-flop circuit 10 includes a D-flip-flop 12 and a clock signal output section 14.

The D-flip-flop 12 includes a data input terminal D, a clock input terminal CK, a reset input terminal RN, an output terminal Q, and an inverted output terminal QN. A data signal is input to the data input terminal D. A clock signal is input to the clock input terminal CK. A reset signal RST_N is input to the reset input terminal RN. The output terminal Q latches the data signal input to the data input terminal D in synchronism with the rise of the clock signal, and outputs an output data signal OUT. The inverted output terminal QN outputs an inverted output data signal obtained by inverting the output data signal OUT output from the output terminal Q.

The clock signal output section 14 is configured by including an XNOR circuit 16 and an OR circuit 18.

A data signal IN is input to one input terminal of the XNOR circuit 16. Further, an output data signal that is output from the data output terminal Q of the D-flip-flop 12, is input to the other input terminal of the XNOR circuit 16. The XNOR circuit 16 outputs a negation signal A which is a negation of the exclusive OR of the data signal IN and the output data signal.

A negation signal A is input to one input terminal of the OR circuit 18. A clock signal CLK is input to the other input terminal of the OR circuit 18. The OR circuit 18 outputs a clock signal B which is an OR of the negation signal A and the clock signal CLK, to the clock input terminal CK of the D-flip-flop 12.

The clock signal output section 14 outputs a clock signal CLK in synchronism with the rise of the clock signal CLK, only when the data signal IN changes.

The output terminal Q of the D-flip-flop 12 is output to a flip-flop circuit (not shown) of a subsequent stage similar to, for example, the flip-flop circuit 10. The flip-flop circuits 10 are connected in plural stages to configure a shift register.

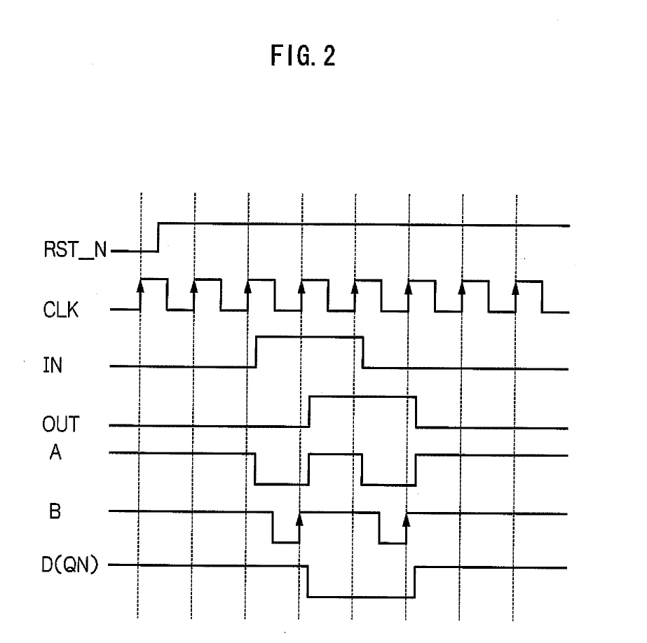

Next, the operation of the flip-flop circuit 10 according to the first exemplary embodiment will be described with reference to a timing chart shown in FIG. 2.

Referring to FIG. 2, when a reset signal RSN_N is at a low level (hereinafter “L”), the D-flip-flop 12 is asynchronously initialized. As a result, the output data signal OUT becomes “L”. Further, when the data signal IN is initialized and becomes “L”, the negation signal A which is output from the XNOR circuit 16 becomes a high level (hereinafter “H”). Further, the OR signal output from the OR circuit 18, also becomes “H”.

When the data signal IN changes from “L” to “H” as shown in FIG. 2, the negation signal A changes to “L”. Accordingly, the clock signal B output from the OR circuit 18 changes to “L” in synchronism with the fall of the clock signal CLK, and changes to “H” in synchronism with the rise of the clock signal CLK. Namely, after the data signal IN changes, the clock signal B is input to the clock input terminal CK of the D-flip-flop 12 only in a period when the negation signal A is “L”.

As described above, the clock signal is input to the clock input terminal CK of the D-flip-flop 12 only when the data signal IN changes. Therefore, the flip-flop circuit 10 according to the first exemplary embodiment can suppress wasteful power consumption.

When the clock signal B becomes “H”, the data signal input to the data input terminal D of the D-flip-flop 12 is latched, and therefore the inverted output data signal of “H” output from the inverted output terminal QN is then latched. Accordingly, the output data signal OUT output from the output terminal Q of the D-flip-flop 12 becomes “H”.

Further, when the data signal IN changes to “L”, the negation signal A changes to “L”. The clock signal B changes to “L” upon the fall of the clock signal CLK, and changes to “H” upon the rise of the clock signal CLK. Namely, after the data signal IN changes, the clock signal B is input to the clock input terminal CK of the D-flip-flop 12 only in a period when the negation signal A is “L”.

When the clock signal B becomes “H”, the data signal input to the data input terminal D of the D-flip-flop 12 is latched, and therefore the inverted output data signal of “L” output from the inverted output terminal QN is latched. Accordingly, the output data signal OUT output from the output terminal Q of the D-flip-flop 12 becomes “L”.

Therefore, the flip-flop circuit 10 operates in the same manner as the flop-flop circuit 120 of the related art as shown in FIG. 14.

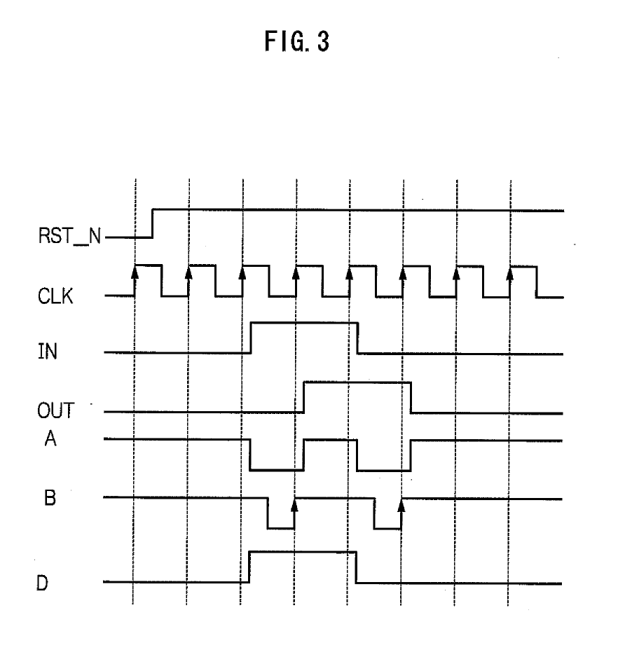

FIG. 3 is a timing chart of the flip-flop circuit 120. In the flip-flop circuit 120 as shown in FIG. 14, the data signal IN is directly input to the data input terminal D of the D-flip-flop 12. Therefore, the only difference between the timing chart of FIG. 3 and the timing chart of FIG. 2 is the signal input to the data input terminal D, and the others are the same.

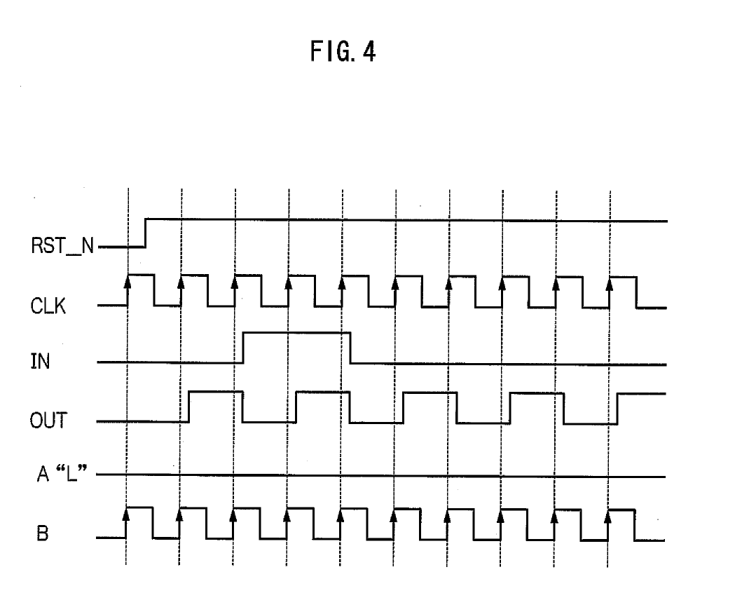

Described below with reference to a timing chart of FIG. 4 is a case where the output of the XNOR circuit 16 is fixed to “L”, due to some cause or fault.

In this case, as shown in FIG. 4, the negation signal A which is an output signal of the XNOR circuit 16 is fixed to “L”. Therefore, the clock signals CLK inputted to the OR circuit 18 are directly outputted as the clock signals B.

Accordingly, the output data signal OUT toggles from “H” to “L” and from “L” to “H” in synchronism with the rise of the clock signal B. Namely, if the output signal of the XNOR circuit 16 is fixed to “L” due to a fault, the output data signal OUT changes into a signal different from that of during the normal operation. Therefore, the flip-flop circuit 10 according to the first exemplary embodiment can detect an abnormal condition.

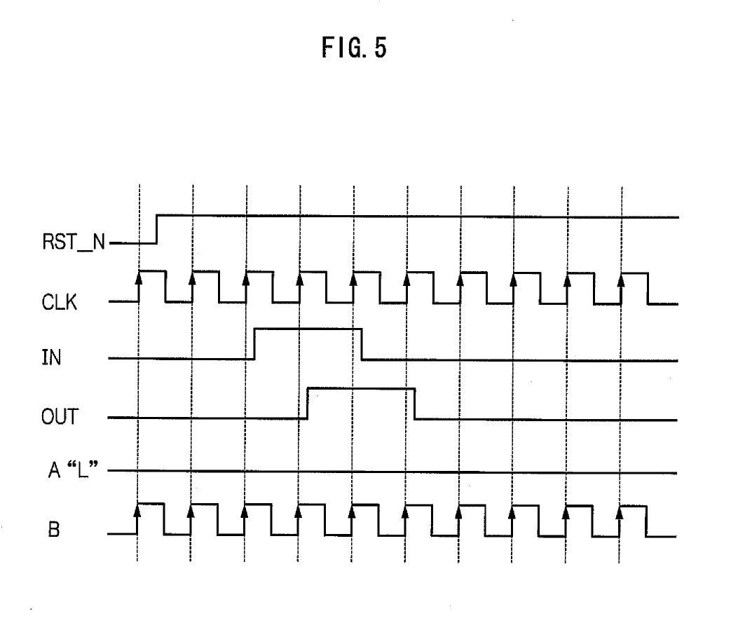

On the other hand, FIG. 5 is a timing chart of the flip-flop circuit 120 of the related art as shown in FIG. 14.

In the flip-flop circuit 120 as shown in FIG. 5, even when the output signal of the XNOR circuit 122 is fixed to “L” due to the fault, the output data signal OUT remains the same as that of during the normal operation shown in FIG. 3. This is because, in the flip-flop circuit 120 shown in FIG. 14, the data signal IN is directly input to the data input terminal D of the D-flip-flop 12.

In the first exemplary embodiment, as described above, the clock signal is input to the clock input terminal CK of the D-flip-flop 12 only when it is necessary (i.e., only when the data signal IN changes). Therefore, the flip-flop circuit 10 of the first exemplary embodiment can suppress wasteful power consumption. Further, the flip-flop circuit 10 of the first exemplary embodiment changes the output data signal OUT into a signal different from the output data signal OUT during the normal operation, when the output signal of the XNOR circuit 16 becomes abnormal. Accordingly, the flip-flop circuit 10 according to the first exemplary embodiment can easily detect an abnormal condition.

### Second Exemplary Embodiment

Next, a second exemplary embodiment of the invention will be described. The second exemplary embodiment describes a flip-flop circuit which enables a scan test to be executed for the flip-flop circuit 10 of FIG. 1. The same portions as those of the flip-flop circuit 10 of FIG. 1 are denoted by the same reference numerals, and therefore the detailed description thereof is omitted.

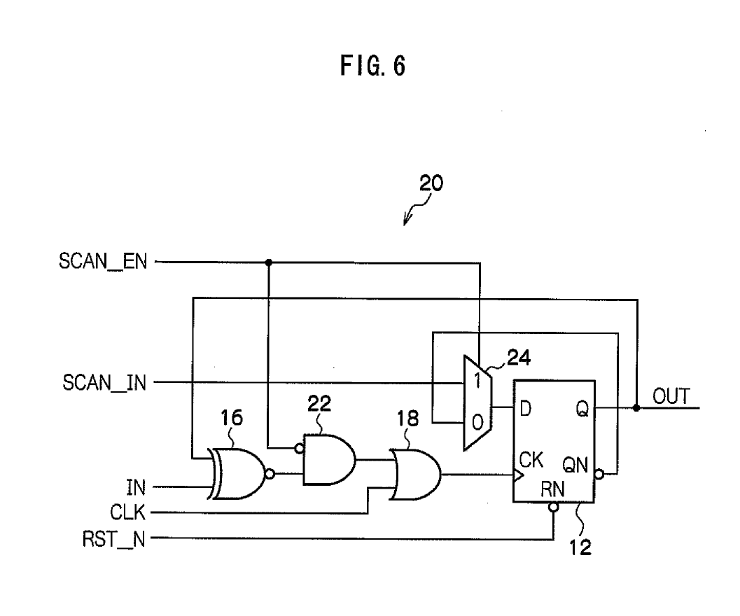

FIG. 6 is a circuit diagram of a flip-flop circuit 20 according to the second exemplary embodiment. As shown in FIG. 6, in the flip-flop circuit 20, an AND circuit 22 and a multiplexer 24 are added to the flip-flop circuit 10 of FIG. 1. Due thereto, a scan enable signal SCAN_EN and a scan data signal SCAN_IN are input to the flip-flop circuit 20.

An inverted signal obtained by inverting the scan enable signal SCAN_EN is input to one input terminal of the AND circuit 22. Further, an output signal of the XNOR circuit 16 is input to the other input terminal of the AND circuit 22. The AND circuit 22 outputs an AND signal, which is an AND of an inverted signal of the scan enable signal SCAN_EN and an output signal of the XNOR circuit 16, to the OR circuit 18.

The scan data signal SCAN_IN is input to one input terminal of the multiplexer 24. An inverted output data signal from the inverted output terminal QN of the D-flip-flop 12 is input to the other input terminal of the multiplexer 24. Further, the scan enable signal SCAN EN is input to a select signal input terminal of the multiplexer 24.

The scan enable signal SCAN_EN becomes “H” during the execution of the scan test and becomes “L” during the normal operation.

The multiplexer 24 outputs the scan data signal SCAN_IN to the data input terminal D of the D-flip-flop 12, when the scan enable signal SCAN_EN input to the select signal input terminal becomes “H”, during the scan test. On the other hand, the multiplexer 24 outputs an inverted output data signal that is output from the inverted output terminal QN to the data input terminal D of the D-flip-flop 12, when the scan enable signal SCAN_EN becomes “L”, during the normal operation.

Therefore, during the normal operation, the output signal of the XNOR circuit 16 is directly output to one input terminal of the OR circuit 18. Further, during the normal operation, the inverted output data signal output from the inverted output terminal QN is input to the data input terminal D of the D-flip-flop 12. Therefore, during the normal operation, the flip-flop circuit 20 according to the second exemplary embodiment operates in the same manner as the flip-flop circuit 10 of FIG. 1.

On the other hand, during the scan test, the output signal of the AND circuit 22 becomes “L”. Therefore, the OR circuit 18 directly outputs the clock signal CLK which is input to the data input terminal D of the D-flip-flop 12. Accordingly, the scan data signal SCAN_IN is latched in synchronism with the rise of the clock input terminal CLK. Further, the scan data signal SCAN_IN is output from the output terminal Q as an output data signal OUT, and is fed to a flip-flop circuit 20 (not shown) of a subsequent stage.

Such flip-flop circuits 20 are connected in plural stages to configure a shift register. In the shift register as configured above, to detect a fault, the operation is normally operated by once setting the scan enable signal SCAN_EN to be “L”. In this case, when the output of any XNOR circuit 16 remains fixed to “L” due to a fault, the output data signal OUT becomes “L” and “H” repetitively as shown in FIG. 4. Then, the signal is output to the flip-flop circuit of the subsequent stage. Thereafter, when the scan enable signal SCAN_EN is set to “H” to establish a scan test mode, the output data signals OUT repetitively becomes “L” and “H” which is successively output to the flip-flop circuit of the subsequent stage. Accordingly, when the output signal of the flip-flop circuit of the final stage is output to an external terminal, a fault can be detected by monitoring the signal output to the external terminal.

### Third Exemplary Embodiment

Next, a third exemplary embodiment of the invention will be described. The first and second exemplary embodiments relates to the flip-flop circuit of the rising edge type. Namely, in the first and second exemplary embodiments, the D-flip-flop latches the data signal input to the data input terminal D and outputs as an output data signal OUT in synchronism with the rise of the clock signal input to the clock input terminal CK. In the third exemplary embodiment, however, describes a flip-flop circuit of the falling edge type. Namely, according to the third exemplary embodiment, the D-flip-flop latches the data signal input to the data input terminal D and outputs it as an output data signal OUT in synchronism with the fall of the clock signal input to the clock input terminal CKN.

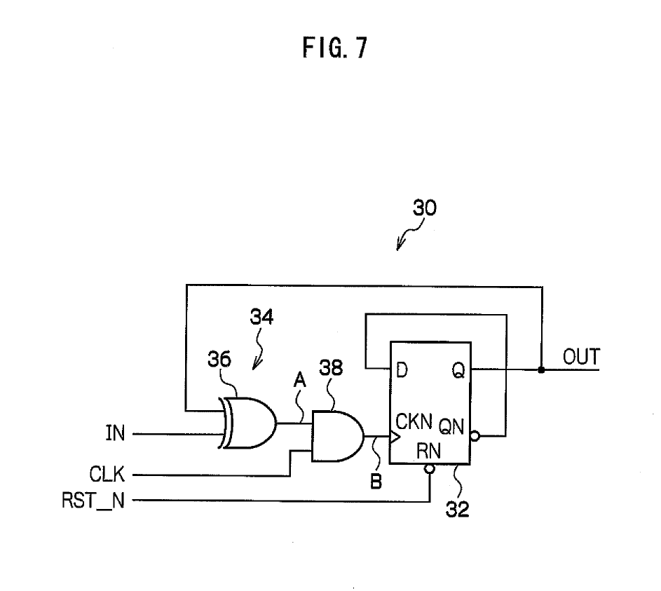

FIG. 7 is a circuit diagram of a flip-flop circuit 30 of the falling edge type. The difference between the flip-flop circuit 30 shown in FIG. 7 and the flip-flop circuit 10 shown in FIG. 1 are: a D-flip-flop 32 is a falling edge type D-flip-flop; a clock signal output section 34 is configured by an XOR circuit 36 and an AND circuit 38; and a signal inverted from an output signal of the XOR circuit 36 is input to one input terminal of the AND circuit 38.

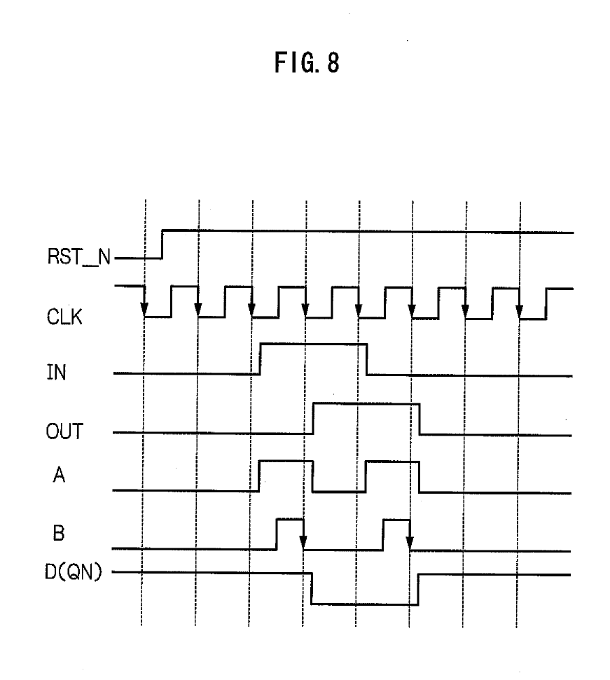

Next, operation of the flip-flop circuit 30 of the third exemplary embodiment will be described with reference to a timing chart of FIG. 8.

Referring to FIG. 8, when a reset signal RSN_N becomes a low level (hereinafter “L”), the D-flip-flop 32 is asynchronously initialized. Moreover, the output data signal OUT becomes “L”. Further, when the data signal IN is initialized to be “L”, a signal A output from the XOR circuit 36 becomes “L”. An AND signal output from the AND circuit 38, also becomes “L”.

When the data signal IN changes from “L” to “H” as shown in FIG. 8, the signal A changes to “H”. Further, a clock signal B output from the AND circuit 38 changes to “H” in synchronism with the fall of the clock signal CLK, and changes to “L” in synchronism with the rise of the clock signal CLK. Namely, after the data signal IN changes, the clock signal B is input to the clock input terminal CKN of the D-flip-flop 32, only in a period when the signal A is “H”.

As described above, the clock signal is input to the clock input terminal CKN of the D-flip-flop 32, only when the data signal IN changes. Therefore, the flip-flop circuit 30 according to the third exemplary embodiment can suppress wasteful power consumption.

When the clock signal B becomes “L”, the data signal input to the data input terminal D of the D-flip-flop 32 (i.e., the inverted output data signal of “H” output from the inverted output terminal QN) is latched. As a result, the output data signal OUT output from the output terminal Q of the D-flip-flop 32 becomes “H”.

Further, when the data signal IN changes to “L”, the signal A changes to “H”. The clock signal B changes to “H” upon the fall of the clock signal CLK, and changes to “L” upon the rise of the clock signal CLK. Namely, after the data signal IN changes, the clock signal B is input to the clock input terminal CKN of the D-flip-flop 32, only in a period when the signal A is “H”.

When the clock signal B becomes “L”, the data signal input to the data input terminal D of the D-flip-flop 32 (i.e., the inverted output data signal of “L” output from the inverted output terminal QN is latched) is latched, and the output data signal OUT output from the output terminal Q of the D-flip-flop 32 becomes “L”.

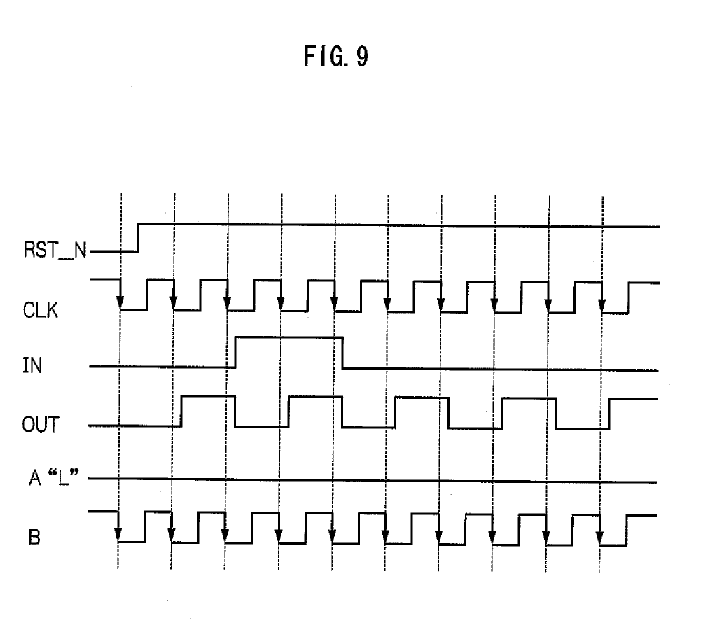

Next, the below describes a case when the output of the XOR circuit 36 is fixed to “H” due to some cause or fault, with reference to a timing chart of FIG. 9.

In this case, as shown in FIG. 9, the signal A output from the XOR circuit 36 is fixed to “H”. Therefore, the clock signals CLK input to the AND circuit 38 are directly output as the clock signals B.

Therefore, the output data signal OUT toggles from “L” to “H” and from “H” to “L” in synchronism with the fall of the clock signal B. Namely, when the output signal of the XOR circuit 36 is fixed to “H” due to a fault, the output data signal OUT changes into a signal different from the output data signal OUT during the normal operation. Therefore, the flip-flop circuit 30 according to the third exemplary embodiment can detect an abnormal condition.

### Fourth Exemplary Embodiment

Next, described below is a fourth exemplary embodiment of the present invention. The fourth exemplary embodiment related to a flip-flop circuit, which enables a scan test to be executed for the flip-flop circuit 30 of FIG. 7. The same portions as those of the flip-flop circuit 30 of FIG. 7 are denoted by the same reference numerals, and therefore the detailed description thereof is omitted.

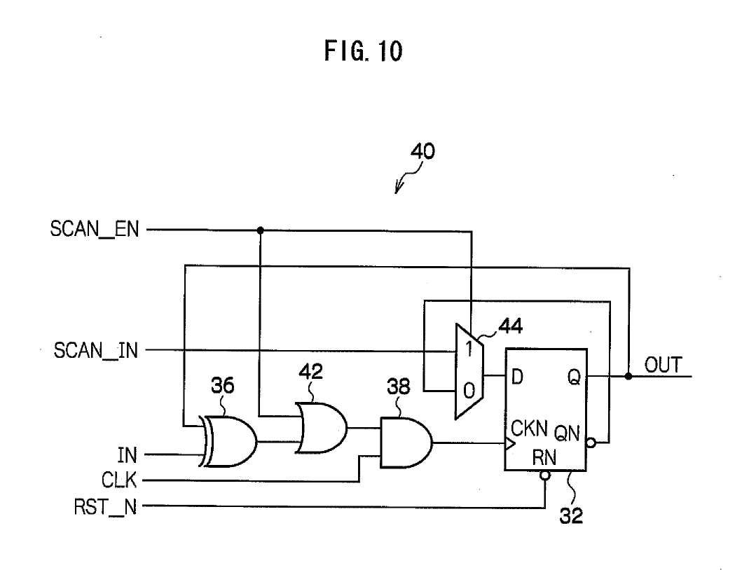

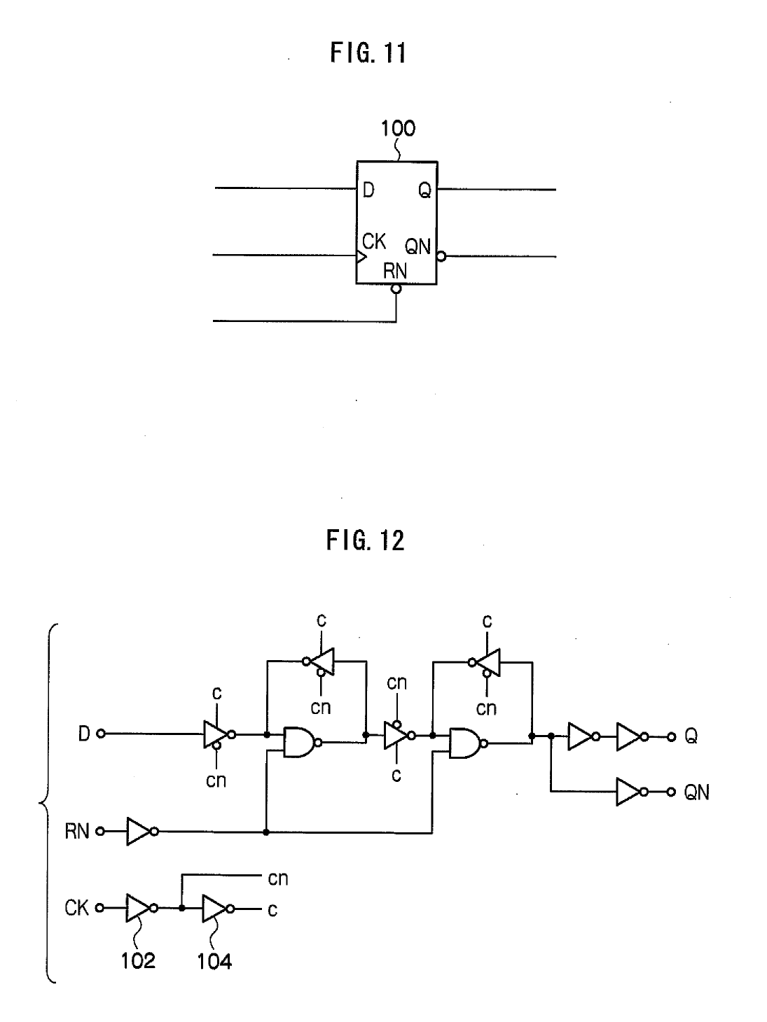

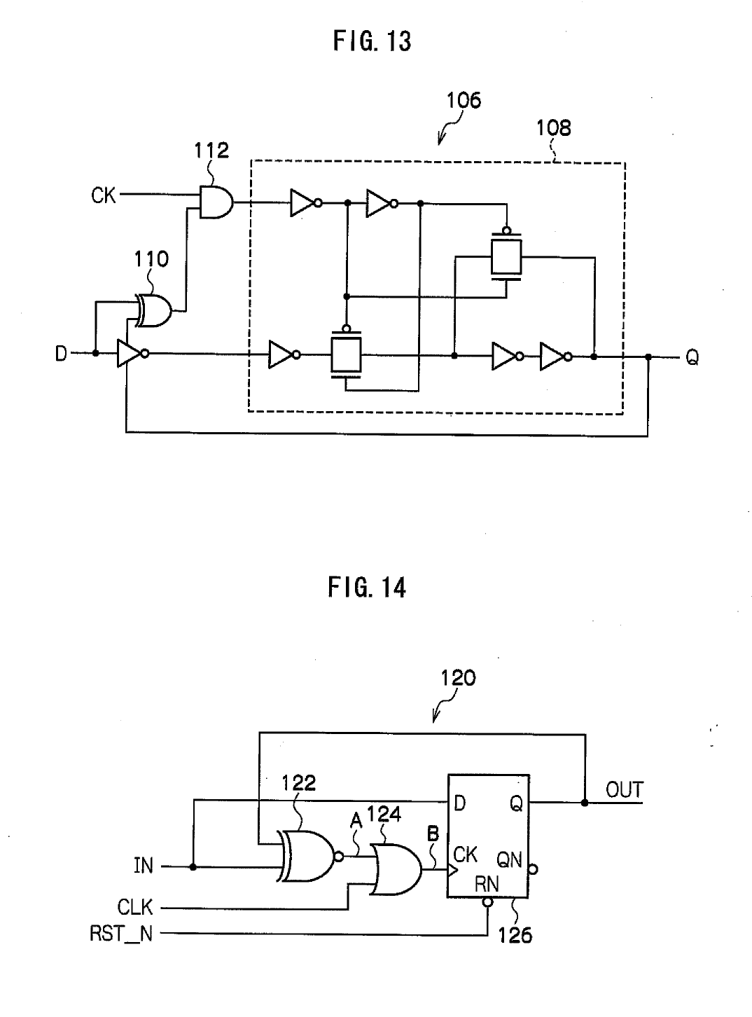

FIG. 10 is a circuit diagram of a flip-flop circuit 40 according to the present exemplary embodiment. As shown in FIG. 10, in the flip-flop circuit 40, an OR circuit 42 and a multiplexer 44 are added to the flip-flop circuit 30 of FIG. 7. Further, the flip-flop circuit 40 is configured to receive a scan enable signal SCAN_EN and a scan data signal SCAN_IN.

A scan enable signal SCAN_EN is inputted to one input terminal of the OR circuit 42. Further, an output signal of the XOR circuit 36 is input to the other input terminal of the OR circuit 42. The OR circuit 42 outputs an AND signal, which is an AND of the scan enable signal SCAN_EN and an output signal of the XOR circuit 36, to the AND circuit 38.

The scan data signal SCAN_IN is input to one input terminal of the multiplexer 44. An inverted output data signal, output from the inverted output terminal QN of the D-flip-flop 32, is input to the other input terminal of the multiplexer 44. Further, the scan enable signal SCAN_EN is input to a select signal input terminal of the multiplexer 44.

The scan enable signal SCAN_EN becomes “H” during the execution of the scan test and becomes “L” during the normal operation.

The multiplexer 44 outputs the scan data signal SCAN_IN to the data input terminal D of the D-flip-flop 32 when the scan enable signal SCAN_EN input to the select signal input terminal becomes “H” (i.e., during the scan test). The multiplexer 44, on the other hand, outputs an inverted output data signal, output from the inverted output terminal QN, to the data input terminal D of the D-flip-flop 32, when the scan enable signal SCAN_EN becomes “L” (i.e., during the normal operation).

Therefore, during the normal operation, the output signal of the XOR circuit 36 is directly output to one input terminal of the AND circuit 38. Further, during the normal operation, the inverted output data signal, output from the inverted output terminal QN, is input to the data input terminal D of the D-flip-flop 32. Therefore, during the normal operation, the flip-flop circuit 40 according to the fourth exemplary embodiment, operates in the same manner as the flip-flop circuit 30 of FIG. 7.

On the other hand, during the scan test, the output signal of the OR circuit 42 becomes “H”. Therefore, the AND circuit 38 directly outputs the clock signal CLK that is input to the data input terminal D of the D-flip-flop 32. Accordingly, the scan data signal SCAN_IN is latched in synchronism with the fall of the clock signal CLK. Further, the scan data signal SCAN_IN is output from the output terminal Q as an output data signal OUT, and is fed to a flip-flop circuit (not shown) of a subsequent stage.

Such flip-flop circuits 40 are connected in plural stages to configure a shift register. In the shift register as configured above, to detect a fault, the operation is normally operated by once setting the scan enable signal SCAN_EN to be “L”. In this case, when the output of any XOR circuit 36 remains fixed to “L” due to a fault, the output data signal OUT becomes “L” and “H” repetitively as shown in FIG. 9. The signal is output to the flip-flop circuit of the subsequent stage. Thereafter, when the scan enable signal SCAN_EN is set to “H” to establish a scan test mode, the output data signals OUT repetitively becoming “L” and “H”, are successively output to the flip-flop circuit of the subsequent stage. Accordingly, when the output signal of the flip-flop circuit of the final stage is output to an external terminal, a fault can be detected by monitoring the signal output to the external terminal.

What is claimed is:

1. A flip-flop circuit comprising:
a clock signal output section that receives a data signal and a clock signal, and outputs the clock signal in synchronism with the rise or the fall of the clock signal when the data signal changes; and
a D-flip-flop including:
a data input terminal that receives an input signal;
a clock input terminal that receives the clock signal;
an output terminal that latches and outputs the input signal in synchronism with the rise or the fall of the received clock signal; and
an inverted output terminal that outputs an inverted output data signal obtained by inverting the output data signal output from the output terminal,
wherein the inverted output terminal of the D-flip-flop is connected to the data input terminal.

2. The flip-flop circuit according to claim 1, wherein:
the output terminal latches and outputs the input signal in synchronism with the rise of the clock signal; and
the clock signal output section includes:
an XNOR circuit that outputs an XNOR signal which is a negation of an exclusive OR of the output data signal and the data signal; and
an OR circuit that outputs an OR signal which is an OR of the XNOR signal and the clock signal.

3. The flip-flop circuit according to claim 2, further comprising:
a selecting section that receives a scan enable signal that represents whether or not to permit an execution of a scan test, a scan data signal for scan test, and the inverted output data signal, that selects either the scan data signal or the inverted output data signal, depending on the scan enable signal, and that outputs the selected signal to the data input terminal; and
an AND circuit that outputs an AND signal which is an AND of a signal obtained by inverting the scan enable signal and the XNOR signal.

4. The flip-flop circuit according to claim 1, wherein:
the output terminal latches and outputs the input signal in synchronism with the fall of the clock signal; and
the clock signal output section includes:
an XOR circuit that outputs an XOR signal which is an exclusive OR of the output data signal and the data signal; and
an AND circuit that outputs an AND signal which is an AND of the XOR signal and the clock signal.

5. The flip-flop circuit according to claim 4, further comprising:
a selection section that receives a scan enable signal that represents whether or not to permit an execution of a scan test, a scan data signal for scan test, and the inverted output data signal, that selects either the scan data signal or the inverted output data signal depending on the scan enable signal, and that outputs the selected signal to the data input terminal; and
an OR circuit that outputs an OR signal which is an OR of the scan enable signal and the XOR signal.
